(19) United States
(12) Patent Application Publication
(10) Pub. No.: US 2018/0278198 A1
(43) Pub. Date: Sep. 27, 2018

(54) TILING FORMAT PHOTOVOLTAIC ARRAY SYSTEM

(71) Applicant: SolarCity Corporation, San Mateo, CA (US)

(72) Inventor: Jason Fisher, Charlottesville, VA (US)

(21) Appl. No.: 15/934,895

(22) Filed: Mar. 23, 2018

Related U.S. Application Data
(60) Provisional application No. 62/477,381, filed on Mar. 27, 2017.

(51) Int. Cl. H02S 20/23; H01L 31/042; H02S 30/10

(52) U.S. Cl. CPC H02S 20/23; H02S 30/10; H01L 31/042

(57) ABSTRACT

Building integrated photovoltaic (BIPV) systems provide for solar panel arrays that can be aesthetically pleasing and appear seamless to an observer. BIPV systems can have photovoltaic (PV) modules configured to be installed to have an appearance similar to traditional roof tiles or slate. Such tiling format PV modules have a number of solar cells appropriate to the surface area and scale of the PV modules. Non-PV tiles can be deployed alongside tiling format PV modules as part of the overall roof surface. Metal pans supporting tiling format PV modules and non-PV tile components of similar size or surface area have a functional advantage in that more areas of a roof installation can be covered by the tiling format PV modules. In some configurations, the appearance of BIPV systems can be particularly aesthetically pleasing and generally seamless to an observer.

### CROSS-REFERENCE TO RELATED APPLICATIONS

This disclosure claims benefit of priority to U.S. Provisional Application 62/477,381, filed on Mar. 27, 2017, and entitled “TILING FORMAT PHOTOVOLTAIC ARRAY SYSTEM”, the entirety of which is herein incorporated by reference.

### TECHNICAL FIELD

This generally relates to photovoltaic arrays, and certain aspects, building integrated photovoltaic arrays.

### BACKGROUND

Solar is becoming increasingly popular in the United States and abroad, but penetration remains relatively low versus the number of homes that could benefit from solar. The price per kilowatt for solar is now competitive with or below that of utility power in most areas, however, solar largely remains a niche product for those who value saving money, reducing CO₂ emissions, or both.

One factor that may limit the adoption of solar technology is aesthetics. Most residential solar systems are installed as modules on an existing tile or composition shingle roof. The solar array, which often only covers a portion of the roof, or even a portion of one mounting plane on the roof, stands out as separate and distinct from the existing roof, both in height and material. This structure is therefore visible even from the street level and over large distances.

Another obstacle to solar adoption in existing homes is the dissonance between the age of the existing roof and the solar system, particularly where the existing roof is covered with composition shingles. The expected life of a solar system and a composition shingle roof are both about 25 years depending on the local climate, but the existing roof may be several years, if not decades, into that lifespan when a prospective customer is contacted. So, the customer may be presented with the dilemma of getting a new roof first, increasing the cost of going solar, or installing a 25-year solar system on a roof, which may have a relatively shorter remaining operational lifespan. Alternatively, the customer may be disqualified based on the condition of the existing roof.

Further, another limiting factor to solar adoption may be the overall surface area of a roof available for solar panels. Some roofs may not be amenable to solar panels of standard or traditional industry sizes, due to available roof surface area, underlying support structures, or other constraints of a particular installation location.

Accordingly, there is a need to resolve the dissonance between the expected life of the solar system, available roof surface, structural support, external constraints, and the remaining life of the roof that also blends in more aesthetically with the complete roof surface, or at least the mounting plane, and that doesn't require the prospective customer to pay for a new roof and a new solar system over that roof.

### BRIEF SUMMARY

Various embodiments provide a new and improved approach to installing solar on existing roofs and/or laying new roofs. Photovoltaic roofing tiles having a particular number of solar cells are mounted over a metal pan structure, where the photovoltaic roofing tiles are of a size more typical of standard (non-photovoltaic) roof tiles, and arranged on a roof accordingly. The number of solar cells per photovoltaic roofing tiles is less than conventional photovoltaic modules as known in the PV industry. The relatively smaller size of the photovoltaic roofing tiles allows for use of a tiling format on a roof, providing for greater flexibility in mounting and arrangement of photovoltaic elements, and potentially increasing the energy collection density for any given photovoltaic array installation. These and other embodiments are discussed in greater detail in the detailed description and drawing figures.

### BRIEF DESCRIPTION OF THE DRAWINGS

Illustrative aspects of the present disclosure are described in detail below with reference to the following drawing figures. It is intended that that embodiments and figures disclosed herein are to be considered illustrative rather than restrictive.

FIG. 1A shows an example of a prior art photovoltaic array installed on a roof.

FIG. 1B shows an exemplary prior art photovoltaic module.

FIG. 2A shows a building integrated photovoltaic system, according to various embodiments of this technology.

FIG. 2B shows an exemplary tiling format photovoltaic module usable with a building integrated photovoltaic system, according to various embodiments of this technology.

FIG. 2C shows an alternative exemplary tiling format photovoltaic module usable with a building integrated photovoltaic system, according to various embodiments of this technology.

FIGS. 3A and 3B show exploded cross-sectional views of photovoltaic modules (as shown in FIGS. 2B and 2C) showing the different layers of the photovoltaic module, according to various embodiments of this technology.

FIG. 4A shows an underlying roof pan structure for a photovoltaic system, according to various embodiments of this technology.

FIG. 4B shows a set of tiling format photovoltaic modules mounted on the roof pan structure shown in FIG. 4A, according to various embodiments of this technology.

FIG. 4C shows the set of tiling format photovoltaic modules shown in FIG. 4B with a set of non-photovoltaic roof tiles surrounding the tiling format photovoltaic modules, according to various embodiments of this technology.

FIG. 4D shows the arrangement of tiling format photovoltaic modules and non-photovoltaic roof tiles shown in FIG. 4C with trim bordering the roof tiles and overall photovoltaic system, according to various embodiments of this technology.

FIG. 5A shows perspective illustration of a roof pan used for implementations of the tiling format photovoltaic module, according to various embodiments of this technology.

FIG. 5B shows a detail cross-sectional view of the overlap connection between roof pan segments shown in FIG. 5A, according to certain embodiments of this technology.

FIG. 6A shows an exemplary tiling format photovoltaic module, according to certain embodiments of this technology.

FIG. 6B shows an exemplary textured roof tile used in combination with tiling format photovoltaic module, according to certain embodiments of this technology.

FIG. 7 shows an exemplary tiling format photovoltaic modules mounted onto a roof pan with mounting brackets, according to various embodiments of this technology.

FIG. 8 shows a perspective view of a corner of a tiling format photovoltaic module mounted onto a roof pan with mounting brackets, according to various embodiments of this technology.

FIG. 9 shows tiling format photovoltaic modules mounted onto a roof pan alongside an textured roof tile, according to various embodiments of this technology.

FIG. 10 shows a side view of a tiling format photovoltaic module with an integrated air channel mounted onto a roof pan with mounting brackets, according to various embodiments of this technology.

FIG. 11A shows an exemplary mounting configuration for a tiling format photovoltaic module and mounting bracket, according to certain embodiments of this technology.

FIG. 11B shows further detail of the exemplary mounting bracket shown in FIG. 11A, according to certain embodiments of this technology.

FIG. 12 shows an exemplary mounting bracket with attachment hardware, according to various embodiments of this technology.

### DETAILED DESCRIPTION

The present disclosure describes various embodiments of photovoltaic roofing systems and associated systems and methods. Some embodiments relate to building integrated photovoltaic module assemblies and associated systems and methods. In various embodiments, the systems described herein lower costs of conventional systems in which a photovoltaic (“PV”) system is installed over a roof, and at the same time can provide an improved aesthetic for a PV roof system.

Certain details are set forth in the following description and in the Figures to provide a thorough understanding of various embodiments of the present technology. Other details describing well-known structures and systems often associated with PV systems, roofs, etc., however, are not set forth below to avoid unnecessarily obscuring the description of the various embodiments of the present technology.

The disclosed PV array and system implements a unique two-part building-integrated system that utilizes a contiguous steel roofing plane or “roof pans” covered in PV modules and/or non-PV roofing tiles that are relatively smaller than standard or traditional PV modules as known in the industry. These reduced size PV modules are referred to herein as “tiling format photovoltaic modules” (which can be alternatively referred to as “mini PV modules”, “reduced size PV modules”, “mini-mods”, or the like). In an exemplary embodiment, the tiling format photovoltaic module can be a panel having twelve (12) solar cells. In another exemplary embodiment, the tiling format photovoltaic module can be a panel having six (6) solar cells. Advantages of tiling format photovoltaic modules include the ability to achieve a greater density of active surface area with photovoltaic cells generating electricity on a given roof.

It can be challenging to optimize the amount of solar energy collected on a residential building roof, because in some cases the available surface area of a roof on a residential building may be limited or of an irregular shape that is not amenable to having a desired number of standard-sized PV modules mounted thereon. Thus, the ability to use smaller PV modules, such as tiling format PV modules, for such installations allows for both a more efficient arrangement of parts and a greater potential for total energy collection and generation.

In some implementations, both tiling format PV modules and standard-sized PV modules can be used in combination, where the wiring electrically connecting the tiling format PV modules and standard-sized PV accounts for any differences in voltage or current such that no one module acts as an electrical bottleneck or load-limiting portion of a circuit.

Steel roof pans use common and inexpensive materials, and can be mounted using standard installation practices. The space between the steel roof pan and the mini-mods mounted on the steel pans can provide multiple advantages. In some aspects, the air space behind the mini-modules provides for a passive cooling of both the PV system and building below the steel pans. This space between the pans and the PV modules is protected from vegetation or rodent ingress, but can use vented flashings to allow for airflow within the space. Further, the space allows for all of the PV system wiring to be protected and kept isolated from other materials (e.g., all the wiring is located above the steel pans).

Further, aspects of the disclosed PV array and system allow for a particularly efficient and straightforward installation process. Specifically, embodiments of the present building integrated photovoltaic system (“BIPV”) use a specialized pan bracket which can be secured to a roofing plane and thereby provide for mounting structures configured to allow for the assembly or removal of a PV array more quickly and with fewer necessary tools than solar panel arrays as traditionally known in the industry. In some exemplary implementations, the specialized pan bracket can be configured to receive and support tiling format photovoltaic modules as considered by the present disclosure.

Many of the details, dimensions, angles and other features shown in the Figures are merely illustrative of particular embodiments. Accordingly, other embodiments can include other details, dimensions, angles and features without departing from the spirit or scope of the present invention. Various embodiments of the present technology can also include structures other than those shown in the Figures and are expressly not limited to the structures shown in the Figures. Moreover, the various elements and features shown in the Figures may not be drawn to scale. In the Figures, identical reference numbers identify identical or at least generally similar elements.

As used herein, the term “substantially” refers to the complete or nearly complete extent or degree of an action, characteristic, property, state, structure, item, or result. For example, an object that is “substantially” uniform in height to another object would mean that the objects are either completely or nearly completely uniform in height. The exact allowable degree of deviation from absolute completeness may in some cases depend on the specific context, however, generally speaking, the nearness of completion will be so as to have the same overall result as if absolute and total completion were obtained.

As used herein, the term “about” is used to provide flexibility to a numerical range endpoint by providing that a given value may be “above” or “below” the value. As used herein, unless otherwise specified, the given value modified by about is modified by ±10%.

Wherever used throughout the disclosure and claims, the term “generally” has the meaning of “approximately” or “closely” or “within the vicinity or range of”. The term “generally” as used herein is not intended as a vague or imprecise expansion on the term it is selected to modify but rather, as a clarification and potential stop gap directed at those who wish to otherwise practice the appended claims but seek to avoid them by insignificant, or immaterial or small variations. All such insignificant, or immaterial or small variations should be covered as part of the appended claims by use of the term “generally”.

As used herein, the term “building integrated photovoltaic system” or “BIPV” generally refers to photovoltaic systems integrated with building materials to form at least a portion of a building envelope. For example, the BIPV system can form the roof or roofing membrane of a building. The BIPV systems described herein can be retrofitted, can be a part of a new construction roof, or a combination of both. The PV modules, PV module pans, or both (depending on the particular embodiment) can be used as the actual building envelope (e.g., roofing membrane) to provide a watertight or substantially watertight seal. In other words, the PV modules may be installed over a metal roof pan or support pan that makes up part of the building envelope.

As used herein, the terms “up-roof” and “down-roof” are used to provide orientation, direction, position, or a reference point relative to or in context of a roof or roofing surface upon which the systems described herein are installed on and/or form a portion of. Up-roof generally refers to an orientation that is relatively closer to the roof ridge while down-roof refers to an orientation that is relatively closer to the roof eave.

As used herein, the singular forms “a”, “an”, and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath”, “below”, “lower”, “above”, “upper”, and the like, may be used herein for ease of description to describe one element or feature's relationship to another element(s) or feature(s) as shown in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below, depending on the context of its use. The device may be otherwise oriented (rotated 90 degrees or at other orientations) and the spatially relative descriptors used herein are interpreted accordingly.

Although the terms “first”, “second”, etc. may be used herein to describe various elements, components, regions, layers and/or sections, it should be understood that they should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

As used herein, the terms “and/or” and “at least one of” include any and all combinations of one or more of the associated listed items.

Generally, PV modules are crystalline-based solar panels, which can be either or both of monocrystalline solar panels or polycrystalline (multi-crystalline) solar panels. The laminate or wafer forming the solar energy-collecting surface of such PV modules can be mechanically coupled, adhered, or bonded to structurally supporting pans and/or back-sheets. In some embodiments, PV modules can include layers of amorphous silicon or thin film variations of solar energy-collecting laminates. Generally, PV pan-module assemblies as considered herein, including PV modules, solar panels and laminates, have individual structures that can be used in combination to form larger solar arrays and/or building structures, as set forth below. Alternatively, thin-film PV modules, such as cadmium telluride, copper indium gallium diselenide (“CIGS”), or amorphous thin-film silicon may be used. In still further embodiments, cells based on perovskite or other as of yet non-commercialized materials may be used. The particular type of cell technology used is a design choice and not critical to the various embodiments of the invention.

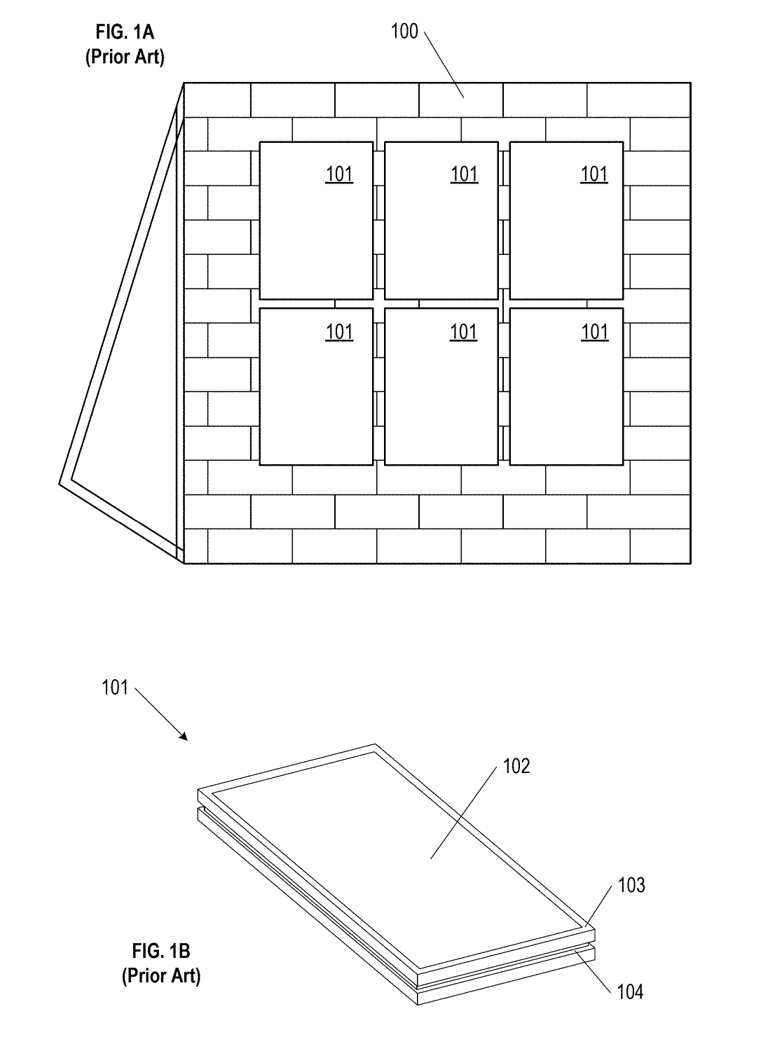

FIG. 1A shows a prior art PV array installed on roof 100. The exemplary PV array of FIG. 1A includes six solar panels 101 or PV modules. Though not shown in detail, solar panels 101 are mounted on roof 100 using one of various known rail-based or rail-free mounting systems, as are currently employed by solar installers.

FIG. 1B shows one type of conventional solar panel 101 in more detail. Solar panel 101 includes PV laminate 102, which in conventional silicon-based cells, consists of a silicon sandwich of p-doped and n-doped silicon layers, a top glass sheet protecting the laminate, and a back sheet that can include a plurality of layers—and rigid metal frame 103, supporting PV laminate 102. Although shown as a unitary structure, laminate 102 may include a plurality of individual solar cells that are wired together to form a single unit encapsulated under the top glass sheet. In the example shown in FIG. 1B, frame 103 is a grooved frame with groove 104 surrounding the outer face of frame 103 on all sides. In such a PV module, groove 104 serves as mechanism for attaching other mounting hardware (e.g., a leveling foot, an interlock) to join modules together and to support the modules over a roof surface. Those of ordinary skill in the art will appreciate that panel 101 may also have a plain, non-grooved frame. Non-grooved frames are typically interconnected to one another and connected to the roof using connectors that clamp down between the top and bottom edges of the frame.

Although these types of framed PV modules achieve their structural function, they are aesthetically suboptimal and have material usage inefficiencies. First, conventional PV systems, such as that shown in FIG. 1A, are typically installed over an existing roof, essentially requiring redundant structure since the PV array will shield most of the portion of the roof that it is installed over. Second, conventional systems are deemed by some people to be unaesthetic. Conventional PV modules usually come in one of two colors: blue, signifying a poly-crystalline silicon structure, and black, signifying a mono-crystalline silicon or thin-film structure. The metal frame portion can be painted black to help it blend in with the roof surface, or it can simply be raw aluminum. Regardless of whether blue or black modules are used, the difference between the look of the portion of the roof that is covered with solar and the remainder of the roof is generally quite dramatic. As a result, roofs that are partially covered with solar panels have an aesthetic contrast that can be seen from very far distances due to the difference in reflectivity, elevation, height, and/or color between these two very different surfaces.

Traditional solar panels known in the industry are often 60-cell, 70-cell, 80-cell, or 92-cell solar panels, and have a size large enough to accommodate such numbers of solar cells. While some solar panels have fewer solar cells per PV module, the size of the underlying pan or substrate retains the standard size, which can accommodate a relatively denser layout of solar cells. Other PV arrays can be formed of electrically connected shingles or tiles, which include one or two solar cell elements per shingle or tile, but such roof construction components, due to their relatively small surface area or form factor, cannot individually support a greater number of solar cells. Thus, a PV system that is in between these two extremes can provide for a maximized number of solar energy collecting structures using tiling format PV modules that are dimensioned to fit on roofs or other surfaces that may not be able to accommodate traditional photovoltaic arrays or full-sized PV panels. Other advantages of a photovoltaic system using such tiling format PV modules is a reduced weight of each PV structure, potentially leading to a relatively lighter overall array, or reducing the need for heavy and robust mounting structures adapted to support traditional PV modules. Such tiling format PV modules can be, for example, 12-cell solar panels. In other aspects or embodiments, such tiling format PV modules can be 2-cell solar panels, 4-cell solar panels, 6-cell solar panels, 8-cell solar panels, 10-cell solar panels, 14-cell solar panels, 16-cell solar panels, 18-cell solar panels, 20-cell solar panels, 22-cell solar panels, or 24-cell solar panels.

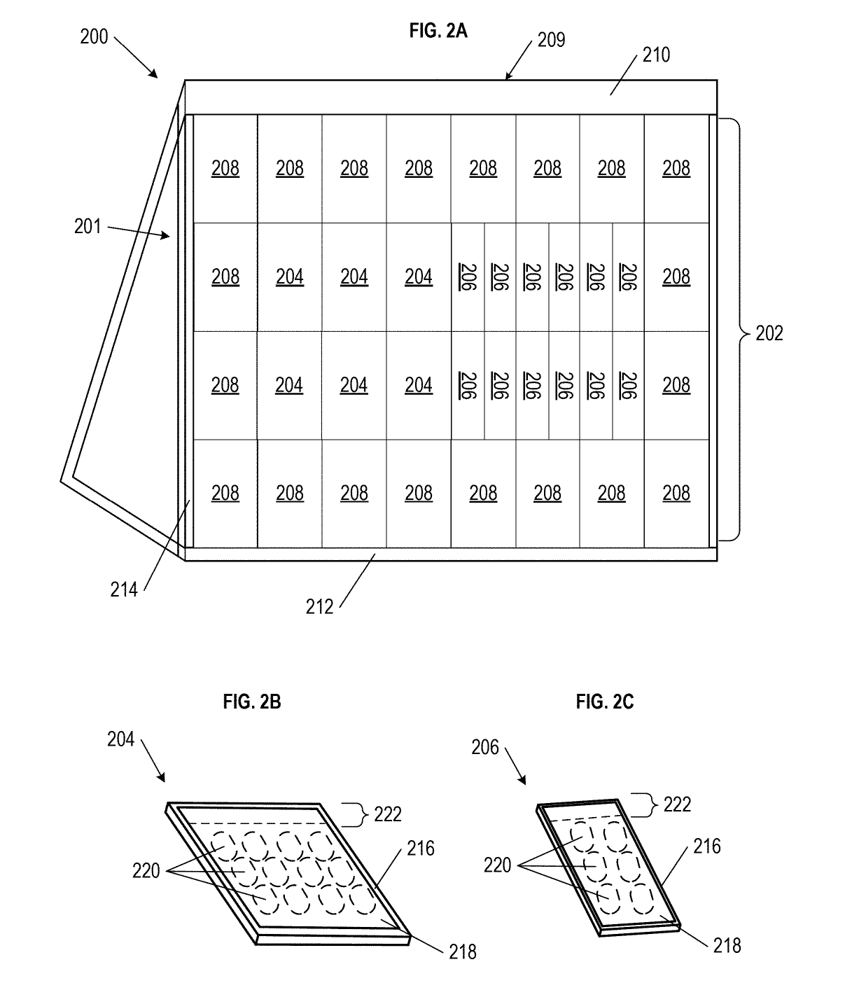

FIG. 2A schematically shows BIPV system 202 installed on plane surface 201 of roof 200. BIPV system 202 can be arranged in vertically aligned columns on existing roof 200 for mounting various PV and/or non-PV modules in an aligned orientation. BIPV system 202 can include tiling format PV modules, where tiling format PV modules shown in BIPV system 202 include both 12-cell PV tiles 204 and 6-cell PV tiles 206 (shown in further detail in FIGS. 2B and 2C). Also shown are non-PV tiles referred to as mimic tiles or simply roofing tiles 208 which can have an appearance similar to 12-cell PV tiles 204, but without solar cells or electricity collecting elements. In some aspects, non-PV roofing tiles 208 used on roof 200 can also include blank tiles, blank tiles being roofing tiles without any PV elements or structures that replicate the appearance of PV elements. Together, these components elements form an integrated photovoltaic roofing system that can improve efficiency and roof surface area coverage when compared conventional PV systems, while providing a generally uniform appearance for roof 200.

BIPV system 202 includes an exemplary solar array of six 12-cell PV tiles 204 and twelve 6-cell PV tiles 206 mounted alongside twenty non-PV roofing tiles 208. As shown, it is appreciated that 12-cell PV tiles 204 and 6-cell PV tiles 206 can generate different amounts of power or voltage, and accordingly underlying circuitry or wiring (e.g., junction boxes, alternators, micro-inverters, DC optimizers, etc.) can be used to regulate or normalize the power output of BIPV system 202. In alternative implementations or installations, the photovoltaic components of BIPV system 202 can include only 12-cell PV tiles 204. In other alternative implementations or installations, the photovoltaic components of BIPV system 202 can include only 6-cell PV tiles 206.

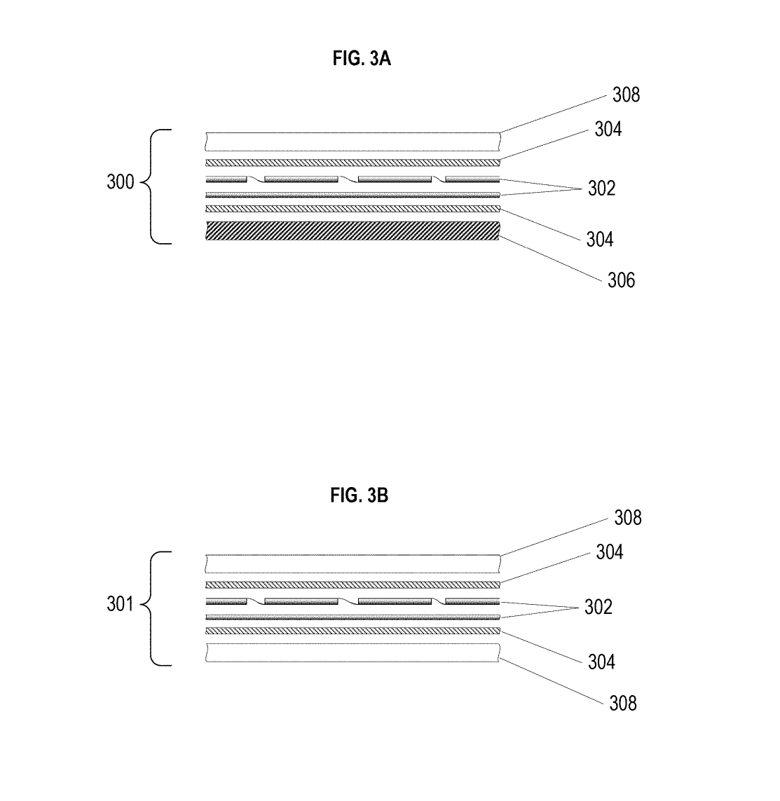

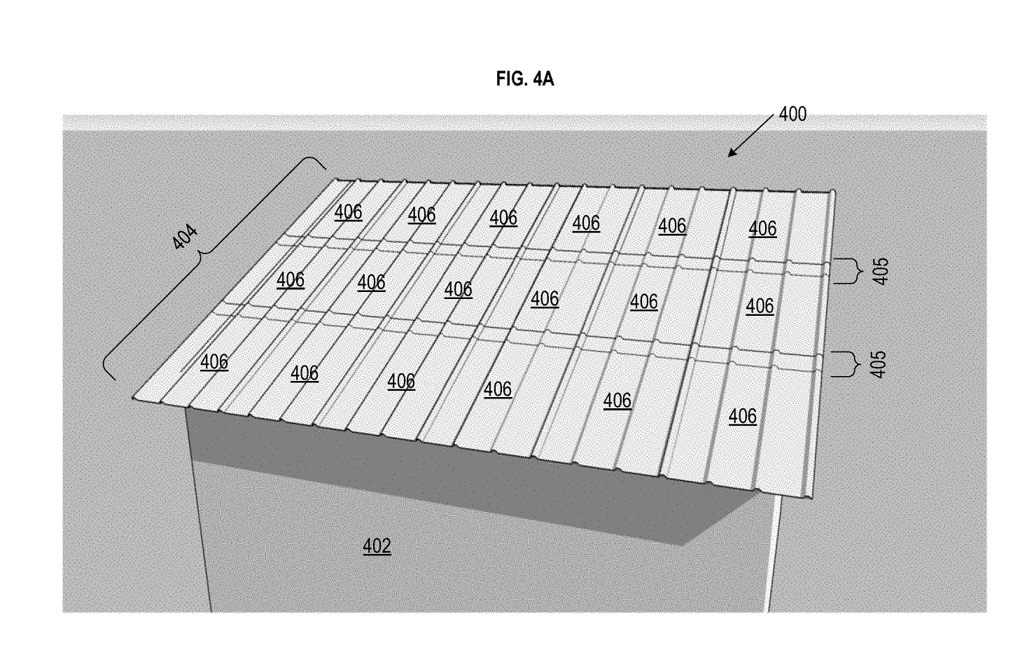

FIG. 2B shows exemplary 12-cell PV tile 204 in further detail, and FIG. 2C shows exemplary 6-cell PV tile 206 in further detail. Tiling format PV modules such as 12-cell PV tiles 204 or 6-cell PV tiles 206 can be frameless or have minimized frame structure 216, as appropriate for a given solar array installation and underlying roof structure. In other words, tiling format PV modules can be constructed without a rigid frame (e.g., made of metal, plastic) surrounding or enclosing the edges of the panel, or in some embodiments, surrounding only a portion of the bottom and sides but not the top of the tiling format PV module. Tiling format PV modules can include layer of top glass 218 and a back-sheet that will sandwich the internal PV layers, including solar cells 220, as described in more detail below with respect to FIGS. 3A and 3B without any framing.

Each of 12-cell PV tiles 204 and 6-cell PV tiles 206 can also include overlap portion 222 (indicated as the area above the dashed line on 12-cell PV tile 204 and 6-cell PV tile 206.) Overlap portion 222 of each tiling format PV module, when mounted and assembled as part of BIPV system 202, is covered by one or more tiling format PV modules from an up-roof row PV modules, or other up-roof structures such as roofing tiles 208. Solar cells 220 are understood to be in the reveal portion of each tiling format PV module.

As shown in FIG. 2A, tiling format PV modules, including both 12-cell PV tiles 204 and 6-cell PV tiles 206, can be placed or mounted on metal roofing pans (discussed in further detail below), where the same metal roofing pans can also be used to mount roofing tiles 208. In such a case, roofing tiles 208 can maintain a uniform appearance alongside tiling format PV modules. In some aspects, roofing tiles 208 can be configured to have a length and width similar to 12-cell PV tiles 204, and in other aspects, roofing tiles 208 can be configured to have a length and width similar to 6-cell PV tiles 206, such that alternative forms of roofing tiles 208 can be mounted alongside 12-cell PV tiles 204 and/or 6-cell PV tiles 206 on roof 200 such that plane surface 201 has a generally uniform appearance.

The generally uniform planar surface 201 of 12-cell PV tiles 204, 6-cell PV tiles 206, and roofing tiles 208 forming BIPV system 202 mounted on metal roofing pans creates a working space in which electrical components can be centralized, ventilation can be achieved, or where access to underlying roof 200 (e.g. sub-roofing, an attic, etc.) can be provided. In particular, circuitry or wiring (e.g., junction boxes, alternators, micro-inverters, DC optimizers, etc.) can be located as part of BIPV system 202 underneath 12-cell PV tiles 204, 6-cell PV tiles 206, and/or roofing tiles 208, but positioned on or over metal roofing pans and/or other structural roofing components. Roof 200 formed with BIPV system 202 in this manner is fully capable of meeting various regulations and requirements related to fire prevention/proofing, structural integrity, and moisture sealing/resistance. In particular, roof 200 formed with BIPV system 202 allows for water shedding of precipitation and other sources of moisture in that individual tiling format PV modules do not need to be assembled to make roof 200 waterproof, but rather water passing over BIPV system 202 can fall on successive rows of tiling format PV modules and/or roofing tiles 208, until falling over the edge of roof 200 formed by eave 212. Alternatively, any water that falls through gaps between rows of tiling format PV modules can be channeled down-roof by metal roofing pans and off of roof 200 through space underneath tiling format PV modules and/or roofing tiles 208 adjacent to eave 212.

Roofing tiles 208 can be substituted for, or configured to appear similar to, tiling format PV modules. For example, roofing tiles 208 can be painted to match in color or appearance of tiling format PV modules. Additionally or alternatively, roofing tiles 208 can include embedded silicon wafer components that are not electrically coupled to solar energy collection circuitry. In some embodiments, roofing tiles 208 can be used to transition from or establish the end panels of BIPV system 202 at up-roof (e.g. at ridge 209 of roof 200) or down-roof portions (e.g., at eave 212 of roof 200) of roof 200. Similarly, in certain embodiments, roofing tiles 208 can be installed adjacent to side portions of roof 200, in place of, or alongside tiling format PV modules, establishing the lateral edges of roof 200 (which are often the East-West sides of roof 200). In other aspects, edge trim 214 (e.g. roof flashing, gutters, etc.) can be used to structurally seal off and terminate the sides of BIPV system 200 on roof 200. In some arrangements of a BIPV system 202, non-PV roofing tiles 208 may be interspersed between tiling format PV modules, which can allow for a desired control of roof 200 appearance or density of solar cells 220 on roof 200.

Roof 200 can include ridge cap 210 to cover roof ridge 209, and may be used to conceal and protect wires (e.g., conduits or cables) or other equipment (e.g., fans, vents, connectors, inverters, jumpers, home-run connections). Roof 200 can also include other roofing components (e.g., flashings, gutters, vents, caps, covers, trims), for example, at eave 212, or at hips, valleys, or lateral sides of the roof (not shown). It can be understood that while FIG. 2A shows BIPV system 202 with 12-cell PV tiles 204 and 6-cell PV tiles 206, other embodiments or implementation of BIPV system 202 can include a solar array with more or less than the exemplary number 12-cell PV tiles 204 and 6-cell PV tiles 206 shown. Indeed, any given installation of BIPV system 202 can use a configuration and number of 12-cell PV tiles 204, 6-cell PV tiles 206, and/or other such tiling format PV module as appropriate for any one or more of plane surface 201 that form overall roof 200.

Again, it is understood that BIPV systems 202 should not be considered limited to embodiments with only 12-cell PV tiles 204 or 6-cell PV tiles 206; in various embodiments, tiling format PV modules can include any number of cells. As noted above, tiling format PV modules can have two solar cells, four solar cells, six solar cells, eight solar cells, ten solar cells, twelve solar cells, fourteen solar cells, sixteen solar cells, eighteen solar cells, twenty solar cells, twenty-two solar cells, twenty-four solar cells, or more than twenty-four solar cells. In other embodiments, tiling format PV modules can have an odd-number of solar cells embedded between top glass 218 and back-sheet. The various embodiments of tiling format PV modules with different numbers of solar cells allows for flexibility in selecting solar panels appropriate for any given system installation or roof 200 surface area.

It should be understood that in these embodiments, roof pitches where such systems are installed are non-zero, and that the systems are installed to account for the angle or slope of (non-flat) roofs. The distances or gaps between various pans, modules, and assemblies, and the degree to which such gaps are concealed will be dependent on roof pitch, the distance a viewer is from the roof, and the height of the viewer.

FIGS. 3A and 3B show in further detail layers 300 of exemplary PV modules, where such PV modules can be used in 12-cell PV tiles 204 or 6-cell PV tiles 206 as shown in FIGS. 2B and 2C. In some embodiments, PV modules solar collection layers 300 described herein refer to crystalline-type (e.g., non-thin film or amorphous solar) solar modules. However, PV modules are not limited to crystalline-type solar cell technology. For example, in other embodiments, thin-film or amorphous solar (e.g., amorphous silicon) can be used as laminate layers with certain embodiments of PV modules described herein. In yet further embodiments, hybrid crystalline and amorphous solar modules can be used with PV modules systems described herein. In other embodiments, other types of solar cells (e.g., non-silicon based semiconductors, partial silicon, non-crystalline, partial crystalline, organic, carbon-based, perovskite, cadmium-telluride, copper-indium-gallium-selenide (“CIGS”), dye sensitized, transparent luminescent solar concentrator, polymer, transparent cells) can be provided as part of PV modules and solar collection layers 300.

As shown in FIG. 3A and noted above, in some embodiments, tiling format PV modules can have solar collection layers 300 embedded within the tile body that include PV layers 302 (e.g., solar cells, semiconductor layers, bussing, insulation, laminate) sandwiched between encapsulation layers 304 (e.g., EVA). PV modules can further include one or more back-sheets 306 (e.g., polyvinyl fluoride film) and/or glass layers 308. As shown in FIG. 3B, solar collection layers 300 of PV modules can include first and second glass layers 308 (e.g., “glass on glass”) sandwiching encapsulation layers 304. The glass on glass PV modules can also eliminate or reduce the need for additional intermediate material layers (e.g., a pan portion, underlayment, felt paper) between a bottom of PV module and existing roofing surfaces, which may otherwise be used for fire protection or other purposes. In certain embodiments, solar collection layers 300 of PV modules can include both glass layer 308 and one or more backsheet layers 306. In yet further embodiments, solar collection layers 300 of PV modules can include one or more additional layers (e.g., transparent coatings, insulation layers, phase change material layers to help with heat transfer) on a top side (e.g. the side of PV module incident to solar energy), rear side (e.g. the side of PV module proximate to the installation surface or roof), or as intermediate layers.

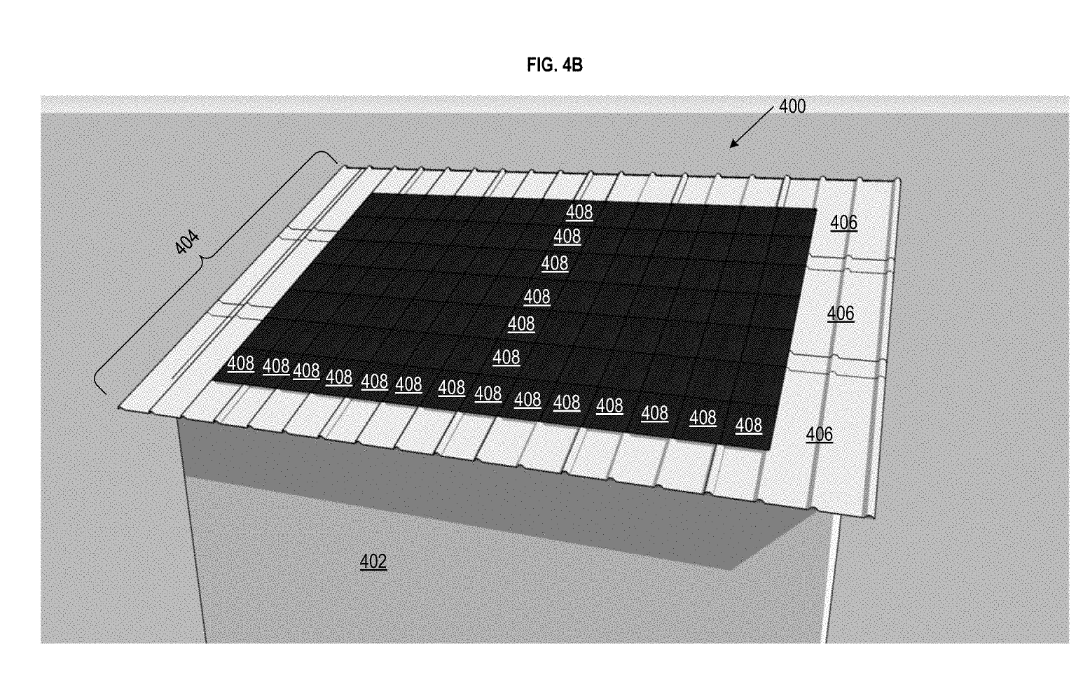

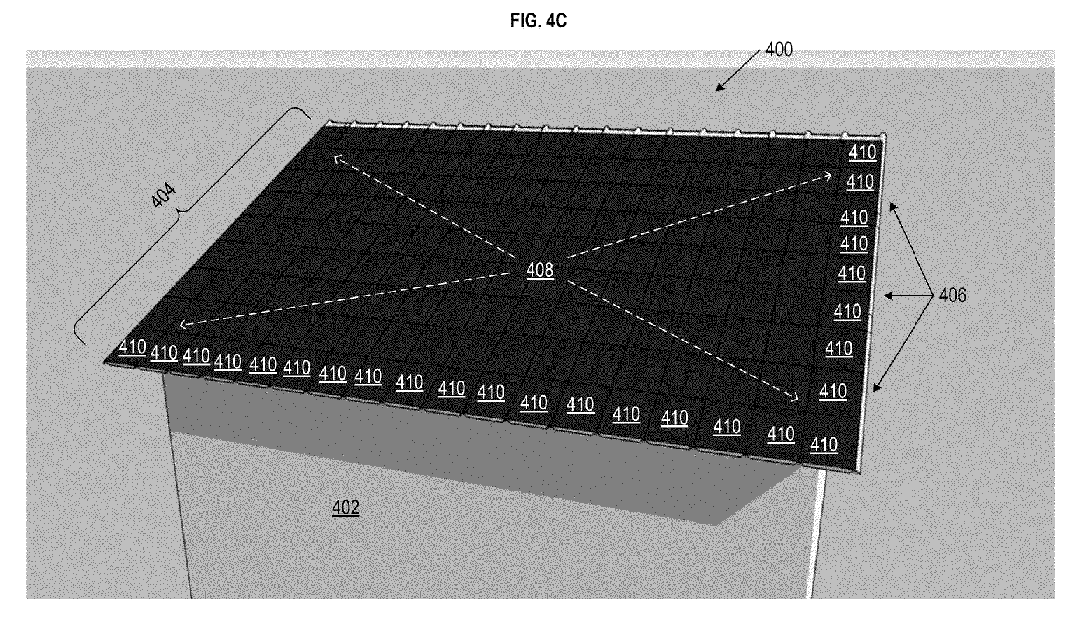

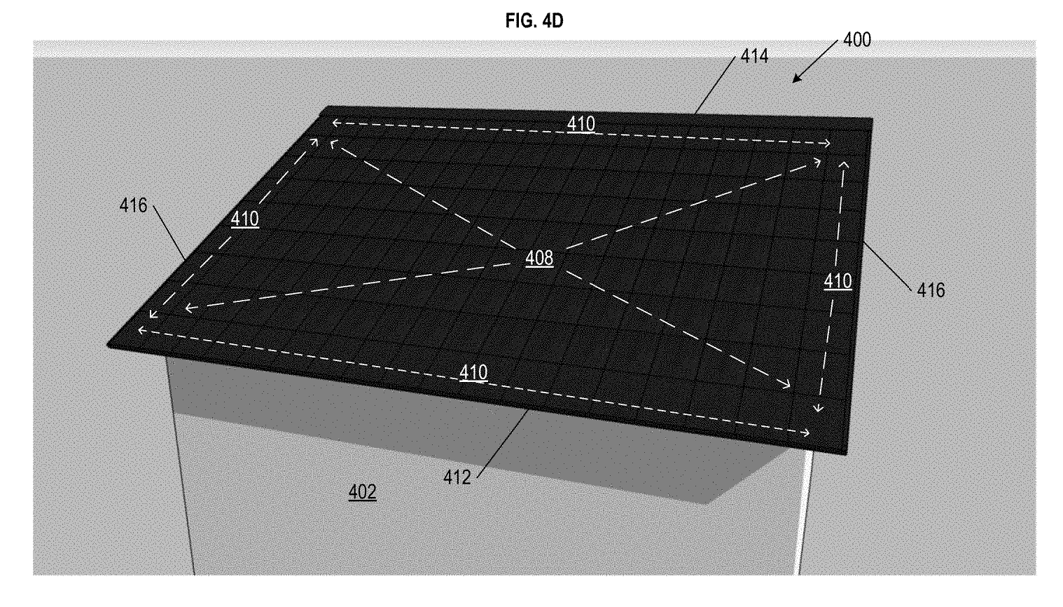

FIG. 4A shows an underlying roof pan structure for a photovoltaic system, specifically, roof 400 on top of structure 402, where roof 400 is covered with or formed by metal roof pans 406. In some embodiments, metal roof pans 406 can be corrugated steel pans, screwed or otherwise secured to a wood deck (not shown) of roof 400, using metal roof materials and components as known in the industry. In other embodiments, metal roof pans 406 can be secured to rafters, battens, joints, or other framing structures (not shown) of roof 400, such that metal roof pans 406 form the envelope of roof 400. Roof edge 404 is shown having an exemplary length equal to three metal roof pans 406, however, it can be understood that any given installation or implementation of metal roof pans 406 on roof 400 can vary in size or arrangement, depending on the area and individual characteristics of underlying structure 402.

In some aspects, felt underlayment can be installed between metal roof pans 406 and a wood deck of roof 400. In other aspects, fire barrier materials (e.g. insulation) may also be included beneath metal roof pans 406 between a wood deck of roof 400. As shown, metal roof pans 406 are partially overlapped (shown as overlap regions 405), where roof pans 406 positioned an up-roof row are laid on top of metal roof pans 406 of an immediately below to allow water to be shed without penetrating the seam between adjacent metal roof pans 406. This water-shedding arrangement of metal roof pans 406 can provide for a primary measure of waterproofing of roof 400.

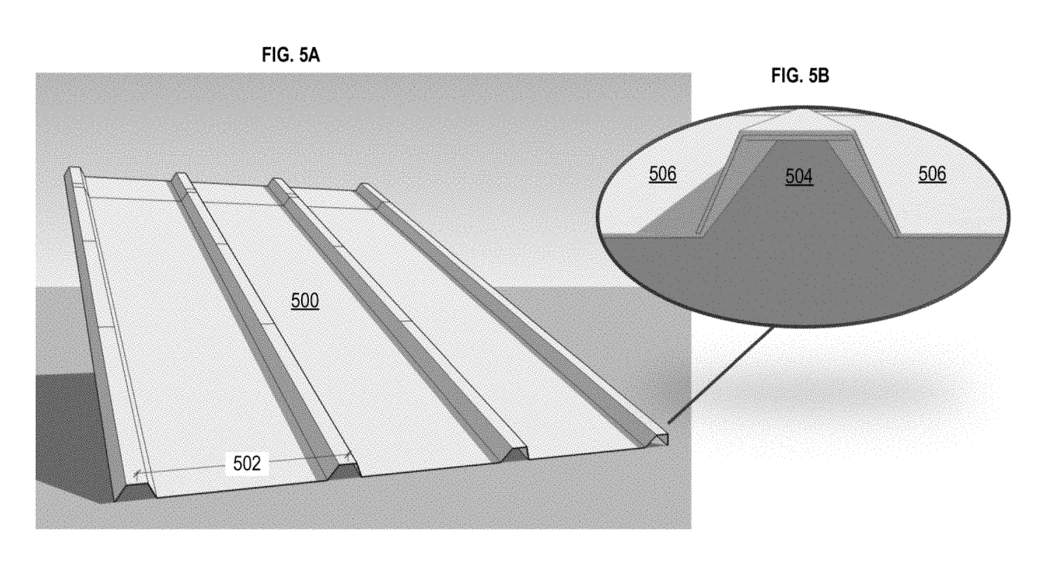

FIG. 4B shows tiling format PV modules 408 mounted on roof 400 formed (at least in part) by metal roof pans 406 as shown in FIG. 4A. (For clarity in FIG. 4B, not every single tiling format PV module 408 is represented with a numerical label.) Tiling format PV modules 408 can be supported by underlying metal roof pans 406, metal roof pans 406 having raised portions (as shown, for example in FIGS. 5A & 5B), where tiling format PV modules 408 rest on or are mounted to. Because metal roof pans 406 sit on and/or are secured to roof 400 or other suitable roof surfaces, accordingly, tiling format PV modules 408 (and also optionally roofing tiles or blank tiles) may not need to be as strong as framed panels in an ordinary or conventional array. In other words, in an ordinary or conventional array, the panel frame can become part of the mounting system and is subject to the same forces and moments as the mounting system, whereas in contrast, the BIPV system as considered herein can have metal roof pans 406 primarily bearing the structural load instead of tiling format PV modules 408.

Tiling format PV modules 408 shown here are 12-cell PV tiles, although BIPV systems as considered herein are not limited to such exemplary embodiments. Further, tiling format PV modules 408 shown here are frameless PV tiles, which do not have metallic edges, and do not have specific hardware to mechanically couple to each other or other portions of roof 400. Rather, it contemplated that each tiling format PV module will have a pair of positive and negative terminals and connectors so that they can be connected serially to form strings of PV module at voltage levels seen in conventional PV systems. Because tiling format PV modules 408 rest on, or are mounted to, the raised portions of metal roof pans 406, there is a space created between the primary (non-raised) surface of metal roof pans 406 and the underside of tiling format PV modules 408. This working space provides for room in which junction boxes, wiring, or other electrical components can be mounted, connected, and arranged. This space also allows air to circulate under the PV modules. In some embodiments, some of tiling format PV modules 408 can be substituted with non-functional units (e.g., non-PV tiles) as desired or needed for power generation or aesthetic purposes.

FIG. 4C shows tiling format PV modules 408 of FIG. 4B and also non-PV roof tiles 410 surrounding tiling format PV modules 408. (For clarity in FIG. 4C, not every single non-PV roof tile 410 is represented with a numerical label. In this figure, tiling format PV modules 408 are identified by arrows indicating the region covered by tiling format PV modules 408.) Non-PV roof tiles 410 elements make up a non-solar area of roof 400. As shown, non-PV roof tiles 410 are positioned to establish the ends of or boundaries of the BIPV system up-roof at the ridge, down-roof at the eave, and along roof edges 404. In the Figure, edges of underlying metal roof pans 406 are still visible and exposed at the side edges, ridge, and eave of roof 400, however, it is contemplated that edge moldings may be utilized to conceal these edges. Both tiling format PV modules 408 and non-PV roof tiles 410 can be arranged such that components of the BIPV system that are positioned relatively up-roof can overlap on top of relatively down-roof components of the BIPV system. This water-shedding arrangement of tiling format PV modules 408 and/or non-PV roof tiles 410 can also provide for a degree of waterproofing of roof 400 as well as mimicking the overlaid texture of a conventional ceramic or cement tile roof.

In some aspects, non-PV roof tiles 410 can be mimic tiles that simulate the appearance of tiling format PV modules 408. In other aspects, non-PV roof tiles 410 can be “blank” tiles which do not have embedded features to simulate the appearance of tiling format PV modules 408, but rather appear similar to traditional roofing tiles. Blank tiles used as non-PV roof tiles 410 can optionally be color-matched to tiling format PV modules 408. In various aspects, non-PV roof tiles 410 can be made from coated steel or polymeric materials. In other aspects, non-PV roof tiles 410 can have a textured surface, which can provide for a desired appearance or add to traction for individuals walking on roof 400.

FIG. 4D shows the arrangement of tiling format PV modules 408 and non-PV roof tiles 410 shown in FIG. 4C with trim bordering the roof tiles and overall BIPV system. (For clarity in FIG. 4D, both tiling format PV modules 408 and non-PV roof tiles 410 are identified by arrows indicating the region covered by tiling format PV modules 408 and non-PV roof tiles 410, respectively.) Specifically, eave flashing 412 is positioned at the eave of roof 400, ridge cap 414 is positioned at the ridge of roof 400, edge flashings 416 are positioned at roof edges 404 of roof 400. In various embodiments, any one or all of eave flashing 412, ridge cap 414, or edge flashings 416 can be are vented to allow for airflow, and concurrently provide protection from any access by unauthorized persons or wildlife.

FIG. 5A is a perspective illustration of roof pan 500 used for implementations of tiling format PV modules and a related BIPV system. Roof pan 500 can be a corrugated steel pan, with raised portions 504 and span 502 between successive raised portions 504 of one or more roof pans 500. In various embodiments, the center-to-center distance between successive raised portions 504, including the width of span 502 can be approximately the same width as tiling format PV modules such that tiling format PV modules can be mounted to, or rested on, successive or adjacent raised portions 504 of roof pans 500. In some embodiments, span 502 of roof pan 500 can be about sixteen inches (16″) in width, as measured from the centerline of one raised portion 504 to an adjacent raised portion 504. In other various embodiments, span 502 of roof pan 500 can be about eight inches (8″) in width, between eight and sixteen inches in width, or greater than sixteen inches (16″) in width. Roof pans 500 can be electrically bonded together and grounded (as per the National Electric Code). Roof pans 500 can overlap at seams between roof pans 500. In some aspects, gasketed metal roofing screws can be used to attach and secure roof pans 500 pans to an underlying wood deck and/or framing structures of a roof.

FIG. 5B is a detail cross-sectional view of roof pan 500 shown in FIG. 5A, particularly illustrating the height of raised portion 504 relative to primary surface plane 506 (in other words, the non-raised portions) of roof pan 500. Raised portion 504 can have a trapezoidal shape, extending upward from primary surface plane 506 of roof pan 500, thereby in part directing any load or weight downward across the full area of roof pan 500.

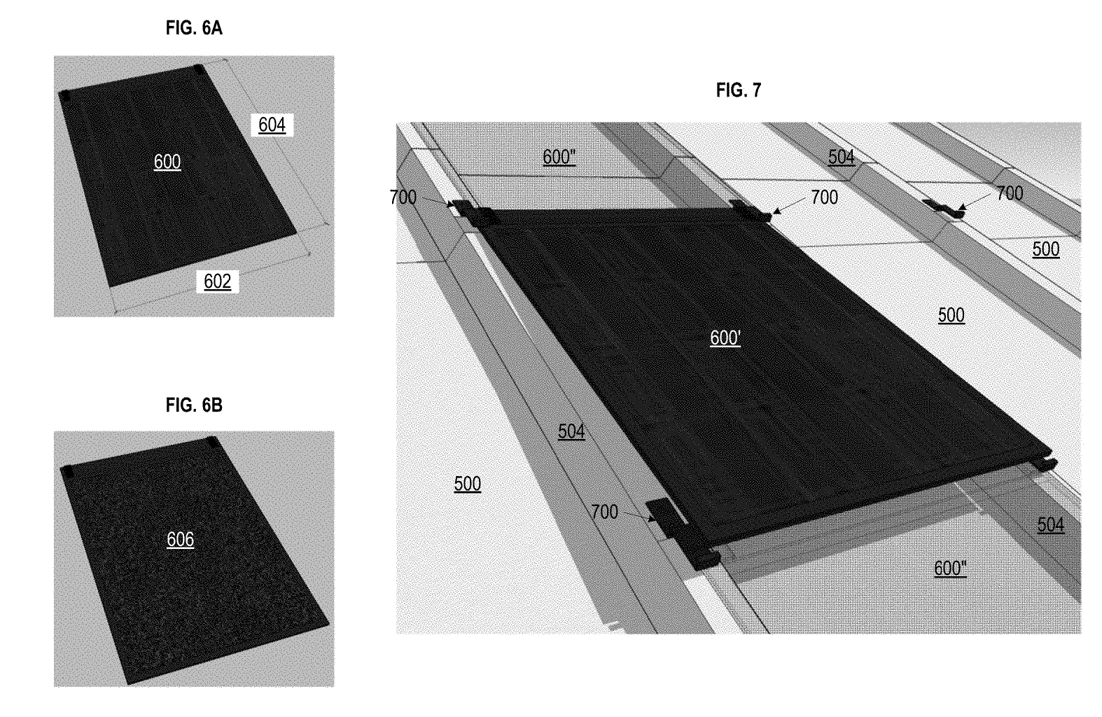

FIG. 6A shows exemplary tiling format PV module 600, having PV tile width 602 and PV tile length 604. In some embodiments, PV tile width 602 can be about sixteen inches (16″). More particularly, PV tile width 602 can be selected or configured to be equal to span 502 of metal pan 500, such that tiling format PV module 600 can be placed on adjacent raised portions 504 of roof pans 500, leaving a working space between tiling format PV module 600 and primary surface plane 506. In some embodiments, PV tile length 604 can be about twenty-two inches (22″), greater than twenty-two inches, or less than twenty-two inches. PV tile length 604 for any given installation of tiling format PV modules 600 can be selected or configured to fit a desired number of rows of tiling format PV modules 600 on a set of metal pans 500 forming at least a section of a roof surface.

FIG. 6B shows exemplary textured roof tile 606 used in combination with tiling format PV modules 600. Textured roof tiles 606 are generally non-photovoltaic, but can otherwise have an appearance similar to tiling format PV modules 600. Textured roof tiles 606 can also have a length and a width the same as PV tile length 604 and PV tile width 602, respectively, such that textured roof tiles 606 have an overall size similar to tiling format PV modules 600 and thereby blend in with tiling format PV modules 600 as part of the same roof installation. Further, textured roof tiles 606, having a width the same as tiling format PV modules 600, can similarly be mounted to, or rested on, successive or adjacent raised portions 504 of roof pans 500.

FIG. 7 shows exemplary central tiling format PV module 600′ mounted onto roof pan 500 with mounting brackets 700 (alternatively referred to as “mounting clips” or “pan brackets”). Generally, four mounting brackets can be used per tiling format PV module 600, securing upper edges and lower edges of tiling format PV module 600 to raised portions 504 of roof pan 500. Mounting brackets 700 can be secured to raised portions 504 such that with tiling format PV module 600 placed on or under mounting brackets 700, mounting brackets 700 are proximate to the four corners of a rectangular tiling format PV module 600. As shown in FIG. 7, central tiling format PV module 600′ is located in the center of the illustration, with two semi-transparent tiling format PV modules 600″ positioned up-roof and down-roof of central tiling format PV module 600′. Semi-transparent tiling format PV modules 600″ are provided to convey the presence of space between tiling format PV modules 600″ and upper surfaces of roof pans 500.

In many aspects, roof pans 500 can have pre-located attachment points adapted to receive mounting brackets 700. Such pre-located attachment points can be set along the length of raised portions 504, generally according to the size of tiling format PV module 600 to be used for a given installation. In some aspects, pre-located attachment points can be set such that the pre-located attachment points on overlapping roof pans 500 align with each other (e.g. in overlap regions 405), and accordingly mounting brackets 700 can be secured to two overlapping roof pans 500.

Mounting brackets 700 are shaped to secure tiling format PV modules 600 (or similarly sized non-PV titles) to raised portions 504 of roof pans 500 by fitting an upper edge of tiling format PV module 600 underneath an L-leg of mounting bracket 700, while also mounting a lower edge of a separate (up-roof and adjacent) tiling format PV module 600 on top of the L-leg of mounting bracket 700. As seen in FIG. 7, lower edge of central tiling format PV module 600′ sit on top of two mounting brackets 700, one mounting bracket 700 located near either lateral side of central tiling format PV module 600′. Further, central tiling format PV module 600′ does not necessarily cover the entire upper L-leg surface of each mounting bracket 700 on which central tiling format PV module 600′ rests. Rather, about half of the upper L-leg surface of each mounting bracket 700 is covered by central tiling format PV module 600′, thereby allowing for further adjacent tiling format PV modules 600 to be mounted immediately to the left and right of central tiling format PV module 600′. Accordingly, a row of tiling format PV modules 600 can be mounted with either one or two tiling format PV modules 600 resting on top of each mounting bracket 700. Further, upper L-leg surface of each mounting bracket 700 can also have a toe or stop on which central tiling format PV module 600′ can rest such that central tiling format PV module 600′ does not slide off of each mounting bracket 700.

Further, immediately down-roof of central tiling format PV module 600′ is one of semi-transparent tiling format PV modules 600″. The upper edge of this semi-transparent tiling format PV module 600″ also uses the same two mounting brackets 700 as central tiling format PV module 600′ to secure to roof pans 500. However, upper edge of this semi-transparent tiling format PV module 600″ is pinned or wedged between a part of lower L-leg surface of each mounting bracket 700 and raised portion 504 of roof pans 500. Accordingly, each tiling format PV module 600 so mounted on a set of mounting brackets 700 will be angled slightly less steep relative to the slope of the underlying roof. This is due to the lower edge of each tiling format PV module 600 being raised higher from the surface of the roof pans 500 than the respective upper edge.

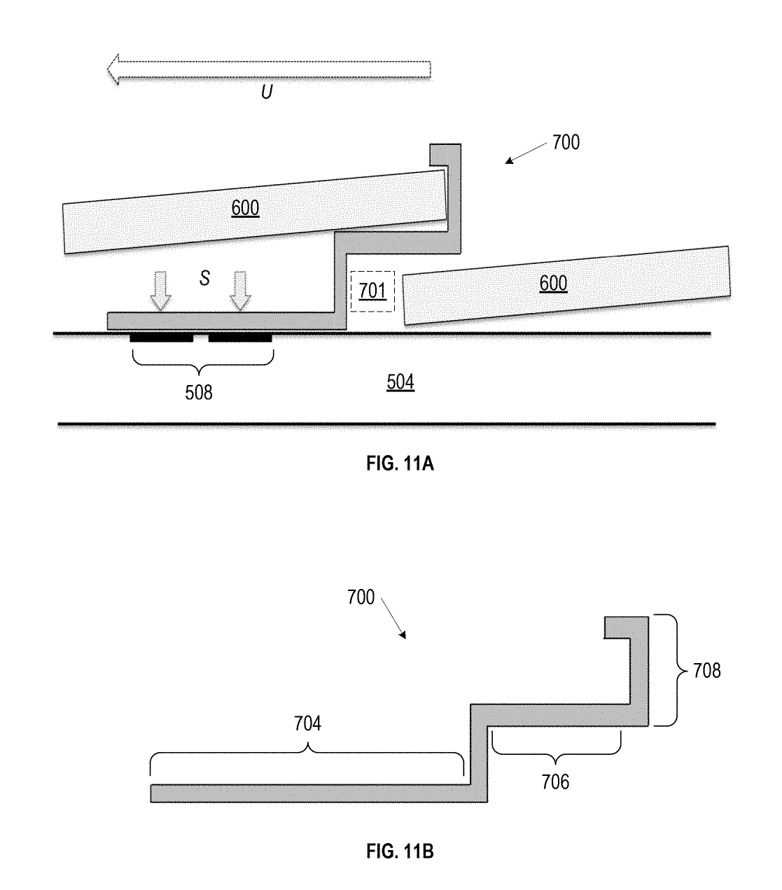

Mounting brackets 700 and tiling format PV modules 600 can be configured to match each other, such that there is an area of slack underneath the L-leg of mounting bracket 700 where tiling format PV module 600 can move within for installation or disassembly of an array (discussed further in FIGS. 11A & 11B).

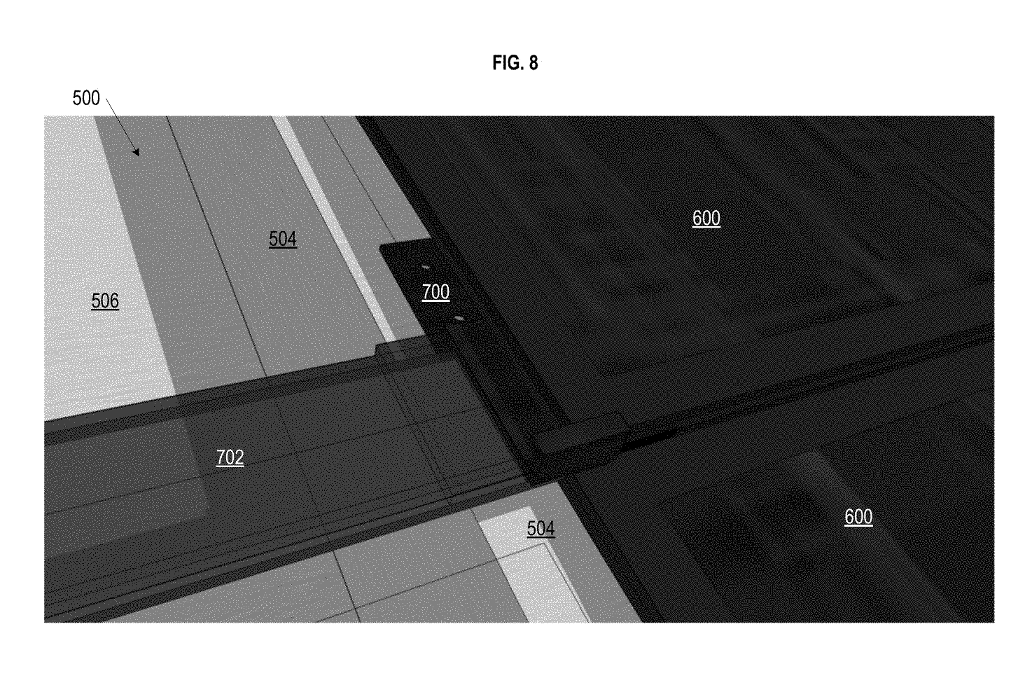

FIG. 8 shows a perspective view of corners of tiling format PV modules 600 mounted onto roof pan 500 at mounting bracket 700. Further, supplementary batten 702 is mounted on roof pan 500 to provide for structure on which tiling format PV modules 600, non-PV tiles, and mounting brackets can be supported. The detail view of FIG. 8 again shows an up-roof tiling format PV module 600 resting on mounting bracket 700, with a down-roof tiling format PV module 600 resting between mounting bracket 700 and raised portion 504 of roof pan 500. Further seen is the gap or space of roof pan 500 above primary surface plane 506 which allows for wiring or other structures to be mounted or run therein. The air cavity that can exist beneath tiling format PV module 600 can be used for cooling and ventilation as well as for locating all wiring. In most aspects, electrical wiring and connections (not shown) for a BIPV system as considered herein are made on top of metal roof pans 500. In some aspects, supplementary batten 702 can function as a brace to provide additional mounting structure. In other aspects, supplementary batten 702 can also have a hollow space in which wiring can be run horizontally over the underlying roof.

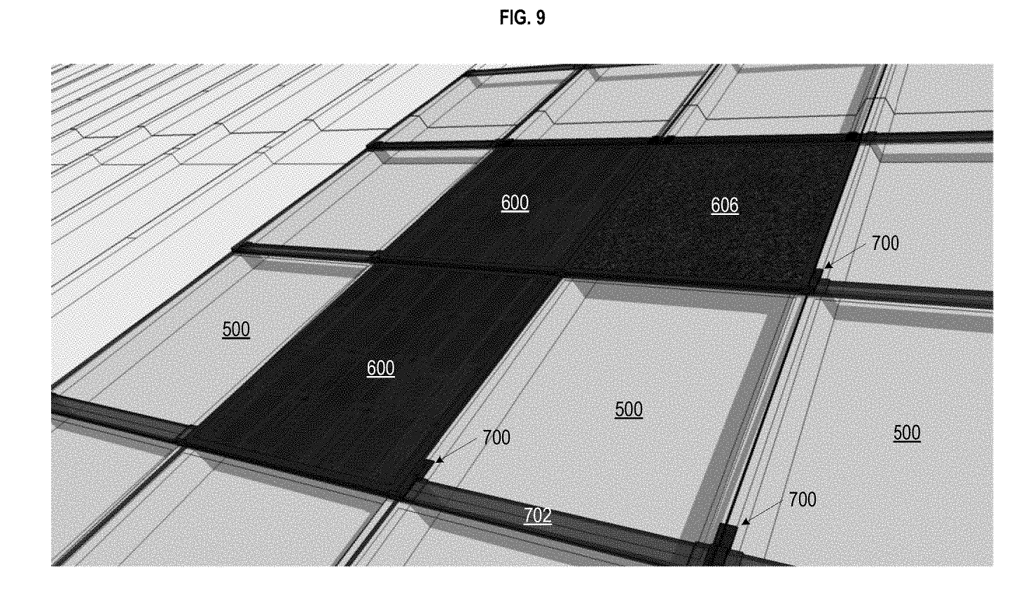

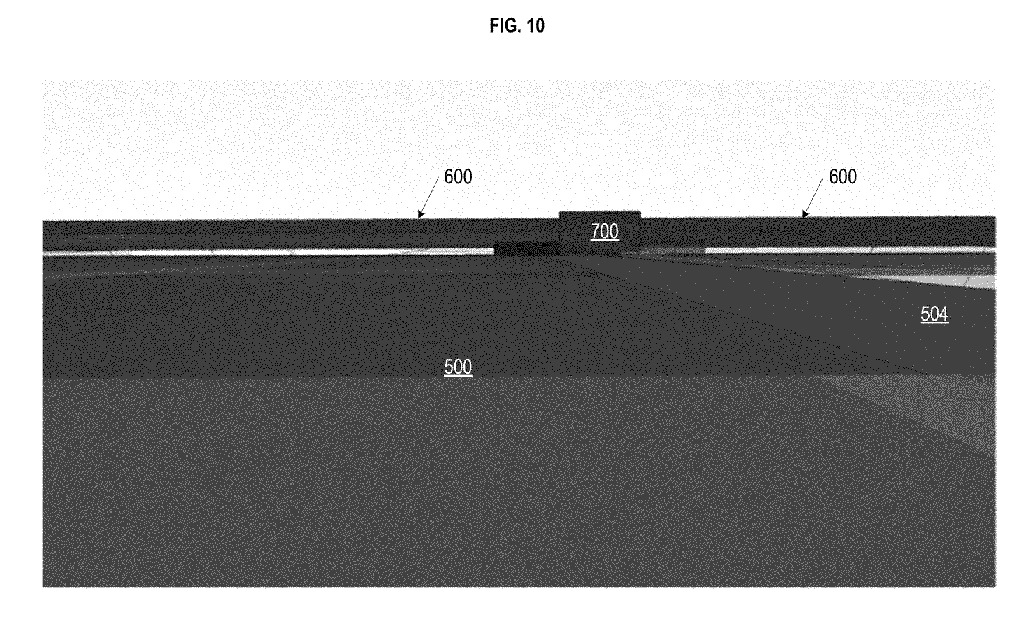

Of note, while FIGS. 8 and 9 show examples of PV array installations using supplementary batten 702, FIGS. 7 and 10 illustrate examples without attachment to such underlying battens. The battenless embodiments of the present disclosure retains adequate and sufficient strength to secure tiling format PV modules to their respective roof pans, able to withstand up-lift from wing, potential slippage due to precipitation, or other environmental factors.

FIG. 9 shows a further exemplary partial installation of tiling format PV modules 600 mounted onto roof pans 500 alongside textured roof tile 606. Both tiling format PV modules 600 and textured roof tile 606 are mounted on roof pans 500 via mounting brackets 700. Supplementary batten 702 is also present at one location on the roof, which can provide for selective structural support or be used as a boundary for a BIPV system using tiling format PV modules 600. It can be understood that electrical connectors coupled to each tiling format PV module, row of tiling format PV modules, or other subset of tiling format PV modules can further couple to each other to conduct electricity as a unified solar array.

FIG. 10 shows a side view of tiling format PV modules 600 mounted onto a raised portion 504 of roof pan 500 on mounting brackets 700. FIG. 10 provides a view looking in the up-roof direction, at the space where the subsequent tiling format PV modules 600 can be inserted and mounted. In many aspects, flexible wiring components can fit in the shown space.

FIG. 11A shows an exemplary mounting configuration for tiling format PV modules 600 and mounting bracket 700, with the up-roof direction indicated by the arrow U. FIG. 11B shows further detail of exemplary mounting bracket 700 shown in FIG. 11A, mounting bracket 700 having base 704, L-leg 706, and toe 708. While the full length of tiling format PV modules 600 are not shown in FIGS. 11A and 11B, it can be understood that the up-roof tiling format PV module 600 extends upward and can be further secured by a subsequent (relatively up-roof) mounting bracket 700, and similarly that down-roof tiling format PV module 600 extends downward and can be further secured by a subsequent (relatively down-roof) mounting bracket 700.

Mounting bracket 700 sits upon raised portion 504 of the metal roof pan, being secured by screws indicated by the arrows S that pass through base 704. In some aspects, screws S passing through base 704 can also pass through a trap top of the underlying roof, through the tape sealant. As shown, screws S secure to raised portion 504 at pre-located attachment points 508 formed within the structure of raised portion 504. The up-roof tiling format PV module 600 has its lower edge sitting on the upper surface of L-leg 706, and extends in the up-roof direction, where its upper edge is secured by another mounting bracket (not shown). Further, the lower edge of up-roof tiling format PV module 600 is held in place on top of mounting bracket 700 by toe 708, which can be configured to receive an edge of tiling format PV module 600. The down-roof tiling format PV module 600 has its upper edge sitting on raised portion 504 and wedged under the lower surface of L-leg 706, and extends in the down-roof direction, where its lower edge is secured by another mounting bracket (not shown).

In various aspects, the exterior corners or transitions between base 704 and L-leg 706, or between L-leg 706 and toe 708, can be curved or chamfered, so as to improve the ease of installing and reduce the risk of damage to tiling format PV modules 600. In other aspects, mounting bracket 700 can also electrically ground tiling format PV modules 600 mounted or resting thereon.

Mounting bracket 700 allow for easy installation and removal of tiling format PV module 600 for service, repair, or inspection. During installation, tiling format PV module 600 can be pushed upward into slack space 701 underneath L-leg 706 of (a relatively up-roof) mounting bracket 700, thereby allowing the lower edge of that tiling format PV module 600 to fit past toe 708 of the next down-roof mounting bracket 700. Once past the point of physical conflict, tiling format PV module 600 can be slid down such that its lower edge rests on L-leg 706 and toe 708. Disassembly of tiling format PV module 600 from such a system is similarly straightforward, where tiling format PV module 600 can be slid upward into slack space 701 of up-roof mounting bracket 700, and lifted by its lower edge past toe 708 of down-roof mounting bracket 700. Moreover, any individual tiling format PV module 600 can be removed and replaced without disturbing neighboring tiling format PV modules 600, thereby improving maintenance processes that require replacement of individual members of such a PV array.

Toe 708 can have a flat structure, a hooked structure (as shown), or other shape as appropriate to a given installation, so long as toe 708 receives a lower edge of tiling format PV module 600 which is held in place due in part to the weight of tiling format PV module 600. In other words, toe 708 can be a ledge extending upward from L-leg 706, on which the lower edges of one or two tiling format PV modules 600 can rest when part of an assembled solar array.

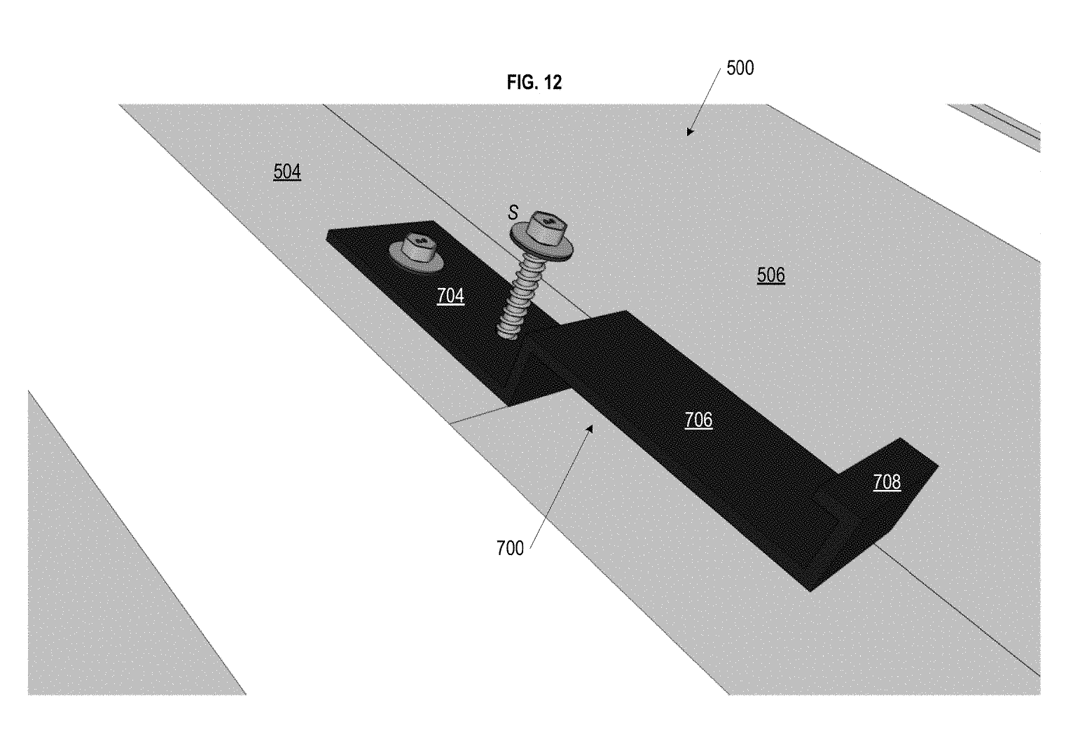

FIG. 12 shows exemplary mounting bracket 700 with base 704, L-leg 706, and toe 708, shown in isolation without PV or non-PV modules mounted thereon. Screws S are shown attaching base 704 into raised portion 504 of metal pan 500. In the Figure, screws S have gaskets to prevent water from seeping under the metal roof pan via the screw threads. Mounting bracket 700 can be formed of a metal or material having the same or different characteristics as metal pans 500, such as hardness, relative weight, tensile strength, and other such material characteristics. Mounting bracket 700 can be cast of a material that has a low risk of damaging surfaces of tiling format PV modules 600.

From the foregoing, it will be appreciated that specific embodiments of the invention have been described herein for purposes of illustration, but that various modifications may be made without deviating from the spirit and scope of the various embodiments of the invention. Further, while various advantages associated with certain embodiments of the invention have been described above in the context of those embodiments, other embodiments may also exhibit such advantages, and not all embodiments need necessarily exhibit such advantages to fall within the scope of the invention. Accordingly, the invention is not limited, except as by the appended claims.

While the above description describes various embodiments of the invention and the best mode contemplated, regardless how detailed the above text, the invention can be practiced in many ways. Details of the system may vary considerably in its specific implementation, while still being encompassed by the present disclosure. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

The teachings of the invention provided herein can be applied to other systems, not necessarily the system described above. The elements and acts of the various examples described above can be combined to provide further implementations of the invention. Some alternative implementations of the invention may include not only additional elements to those implementations noted above, but also may include fewer elements. Further any specific numbers noted herein are only examples; alternative implementations may employ differing values or ranges, and can accommodate various increments and gradients of values within and at the boundaries of such ranges.

References throughout the foregoing description to features, advantages, or similar language do not imply that all of the features and advantages that may be realized with the present technology should be or are in any single embodiment of the invention. Rather, language referring to the features and advantages is understood to mean that a specific feature, advantage, or characteristic described in connection with an embodiment is included in at least one embodiment of the present technology. Thus, discussion of the features and advantages, and similar language, throughout this specification may, but do not necessarily, refer to the same embodiment.

Furthermore, the described features, advantages, and characteristics of the present technology may be combined in any suitable manner in one or more embodiments. One skilled in the relevant art will recognize that the present technology can be practiced without one or more of the specific features or advantages of a particular embodiment. In other instances, additional features and advantages may be recognized in certain embodiments that may not be present in all embodiments of the present technology.

Any patents and applications and other references noted above, including any that may be listed in accompanying filing papers, are incorporated herein by reference. Aspects of the invention can be modified, if necessary, to employ the systems, functions, and concepts of the various references described above to provide yet further implementations of the invention.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application in reference to the text, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Although certain aspects of the invention are presented below in certain claim forms, the applicant contemplates the various aspects of the invention in any number of claim forms. Accordingly, the applicant reserves the right to pursue additional claims after filing this application to pursue such additional claim forms, in either this application or in a continuing application.

1. A solar roof, comprising:
a roof deck;
a plurality of metal roof pans arranged on the roof deck in columns substantially covering the roof deck from a roof ridge to a roof eave, wherein the metal roof pans have raised portions that are evenly spaced apart from one another and oriented along an axis running from the ridge to the eave;
a plurality of mounting brackets having a leg with both an upper surface and a lower surface, wherein the mounting brackets are secured to raised portions of the metal roof pans and form a slack space between the mounting bracket leg and the raised portions of the metal roof pans; and
a plurality of tiling format photovoltaic modules, each having lower edges configured to rest on top of the upper surface of mounting bracket legs and upper edges configured to fit within the slack space formed between the mounting bracket leg and the raised portions of the metal roof pans so that adjacent rows of modules partially overlap one another.

2. The solar roof of claim 1, wherein each mounting bracket further comprises a base that is mechanically secured to the raised portion of metal mounting pans.

3. The solar roof of claim 1, wherein each mounting bracket further comprises a toe that extends upward from the leg and provides for a ledge on which one or two tiling format photovoltaic modules can rest.

4. The solar roof of claim 1, wherein each tiling format photovoltaic module is mounted as part of the solar roof to four mounting brackets, with one mounting bracket proximate to each corner of the tiling format photovoltaic module.

5. The solar roof of claim 1, wherein a working space is formed between non-raised portions of metal roof pans and the plurality of tiling format photovoltaic modules that is adapted to ventilate the solar roof.

6. The solar roof of claim 1, wherein a working space is formed between non-raised portions of metal roof pans and the plurality of tiling format photovoltaic modules that is adapted allow for the mounting of wiring and electronic coupling components of the plurality of tiling format photovoltaic modules.

7. The solar roof of claim 1, wherein each of the tiling format photovoltaic modules comprises twelve solar cells.

8. The solar roof of claim 1, wherein each of the tiling format photovoltaic modules comprises six solar cells.

9. The solar roof of claim 1, further comprising a plurality of non-photovoltaic mimic tiles having an appearance similar to the tiling format photovoltaic modules, and having lower edges configured to rest on top of the upper surface of mounting bracket legs and upper edges configured to fit within the slack space formed between the mounting bracket leg and the raised portions of the metal roof pans.

10. The solar roof of claim 1, wherein the plurality of metal roof pans partially overlap each other within the columns of metal roof pans.

11. The solar roof of claim 1, wherein the tiling format photovoltaic modules are arranged to shed precipitation or other moisture that lands on the solar roof.

12. A building integrated photovoltaic (BIPV) array system for a roof, comprising:
a corrugated metal pan having raised portions running along the length of the corrugated metal pan and a primary surface plane between the raised portions;
mounting brackets secured to the raised portions of the corrugated metal pan, each mounting bracket having a base section, an L-leg section, and a toe section; and
a tiling format photovoltaic module having lower edges and upper edges, wherein the tiling format photovoltaic module is supported on the corrugated metal pan by four mounting brackets, and wherein a working space is formed between the tiling format photovoltaic module and the primary surface plane of the corrugated metal pan.

13. The BIPV array system of claim 12, wherein a span between two adjacent raised portions of the corrugated metal pan is approximately equal to a width of the tiling format photovoltaic module.

14. The BIPV array system of claim 12, wherein the upper edges of the tiling format photovoltaic module are configured to wedge between the at least one mounting bracket leg and the raised portions of the corrugated metal pan.

15. The BIPV array system of claim 12, wherein the lower edges of the tiling format photovoltaic module are configured to sit upon at least one mounting bracket leg.

16. The BIPV array system of claim 12, wherein each of the mounting brackets are adapted to receive one or two tiling format photovoltaic modules.

17. The BIPV array system of claim 13, wherein width of the tiling format photovoltaic module is about sixteen inches (16″) and the tiling format photovoltaic module includes twelve solar cells.

18. The BIPV array system of claim 12, further comprising a mimic tile, supported on the corrugated metal pan by four mounting brackets, expanding the working space between the tiling format photovoltaic module and the primary surface plane.

19. The BIPV array system of claim 18, wherein mimic tile and the tiling format photovoltaic module both rest on the same two mounting brackets.

20. A building integrated photovoltaic (BIPV) roofing system, comprising:
two or more metal roofing pans, each metal roofing pan having raised portions running along the length of the roofing pan and pre-located attachment points distributed along the length of the raised portions;
a plurality of pan brackets, secured to the raised portions of the metal roofing pans at the pre-located attachment points;
at least one tiling format photovoltaic module, having an upper edge and a lower edge, the tiling format photovoltaic module upper edge being secured between one of the metal roofing pans and at least one of the pan brackets, and the tiling format photovoltaic module lower edge resting on at least one of the other pan brackets; and
at least one roofing tile, having an upper edge and a lower edge, the roofing tile upper edge being secured between one of the metal roofing pans and at least one of the pan brackets, and the roofing tile lower edge resting on at least one of the other pan brackets.
